(19) United States
(12) Patent Application Publication
(10) Pub. No.: US 2019/0153307 A1
(43) Pub. Date: May 23, 2019

(54) A COLOR CONVERSION SHEET AND AN OPTICAL DEVICE

(71) Applicants: Merck Patent GmbH, Darmstadt (DE); AZ Electronic Materials (Luxembourg) S.A.R.L., Luxembourg (LU)

(72) Inventors: Bernhard RIEGER, Muenster-Altheim (DE); Christian MATUSCHEK, Frankfurt am Main (DE); Ralf GROTTENMUELLER, Wiesbaden (DE)

(73) Assignees: Merck Patent GmbH, Darmstadt (DE); AZ Electronic Materials (Luxembourg) S.A.R.L., Luxembourg (LU)

(21) Appl. No.: 16/089,527

(22) PCT Filed: Mar. 29, 2017
(86) PCT No.: PCT/EP2017/057360

§ 371 Date: Sep. 28, 2018

(30) Foreign Application Priority Data
Mar. 31, 2016 (EP) 16163344.1

(51) Int. Cl. C09K 11/02; F21V 9/30; H01L 33/50; H01L 33/56

(52) U.S. Cl. CPC C09K 11/02; F21V 9/30; F21Y 2115/10; H01L 33/507; H01L 33/56; H01L 33/502

(57) ABSTRACT

The present invention relates to a color conversion sheet (100) and an optical device comprising a color conversion sheet (100). The present invention further relates to a use of the color conversion sheet (100) in an optical device (200). The invention further more relates to method for preparing the color conversion sheet (100) and method for preparing the optical device (200).

### FIELD OF THE INVENTION

The present invention relates to a color conversion sheet (100) and an optical device comprising a color conversion sheet (100). The present invention further relates to a use of the color conversion sheet (100) in an optical device (200). The invention further more relates to method for preparing the color conversion sheet (100) and method for preparing the optical device (200).

### BACKGROUND ART

A nanosized fluorescent material, color conversion sheet including a fluorescent material and optical devices comprising a light conversion sheet are used in a variety of optical applications, especially for optical devices.

For example, as described in US2014/0264196 A1, WO2014/093391 A2, WO2014/208356 A1, WO2014/196319 A1, WO 2012/132239 A1.

### PATENT LITERATURE

### 1. US2014/0264196 A1

### 2. WO2014/093391 A2

### 3. WO2014/208356 A1

### 4. WO2014/196319 A1

### 5. WO 2012/132239 A1

### SUMMARY OF THE INVENTION

However, the inventors newly have found that there is still one or more of considerable problems for which improvement is desired, as listed below.
1. A novel light conversion sheet comprising a nanosized fluorescent material such as quantum sized materials, and a matrix material, which can show improved thermal stability, is desired.
2. A novel light conversion sheet comprising a nanosized fluorescent material such as quantum sized materials, and a matrix material, which can keep good absolute quantum yield, especially in a thermal stress environment, is required.
3. A novel light conversion sheet comprising a nanosized fluorescent material such as quantum sized materials, and a matrix material, which can fit to lower temperature sheet preparation process well.
4. A novel light conversion sheet comprising a nanosized fluorescent material such as quantum sized materials, and a matrix material, which can fit to wet preparation process well.

The inventors aimed to solve one or more of the aforementioned problems.

Surprisingly, the inventors have found a novel color conversion sheet (100) comprising at least one nanosized fluorescent material (110), a matrix material (120) and a barrier layer (130), wherein the barrier layer (130) is placed onto the outermost surface of the matrix material (120), solves one or more of the problems 1 to 4.

In another aspect, the invention relates to use of the color conversion sheet (100) in an optical device.

In another aspect, the invention further relates to an optical device (200) comprising the color conversion sheet (100).

In another aspect, the invention further relates to an optical device (200) comprises at least one nanosized fluorescent material (210), a matrix material (220), a barrier layer (230), and a light emitting diode element (240), wherein the barrier layer (230) is placed onto the outermost surface of the matrix material (220).

In another aspect, the present invention furthermore relates to method for preparing the color conversion sheet (100), wherein the method comprises following steps (a) and (c) in this sequence;
(a) providing at least one nanosized fluorescent material (110), and a matrix material (120) onto a substrate,
(b) providing perhydropolysilazane solution onto the surface of the matrix material, and
(c) exposing the perhydropolysilazane to vacuum ultraviolet light.

In another aspect, the present invention furthermore relates to method for preparing the optical device (200), wherein the method comprises following step (A);

(A) providing the color conversion sheet (100) in an optical device.

Further advantages of the present invention will become evident from the following detailed description.

### DESCRIPTION OF DRAWINGS

FIG. 1 shows a cross sectional view of a schematic of one embodiment of a color conversion sheet (100).

FIG. 2 shows a cross sectional view of a schematic of one embodiment of an optical device (200) of the invention.

FIG. 3 shows a cross sectional view of a schematic of another embodiment of an optical device of the invention.

FIG. 4 shows the measurement results of working example 5.

FIG. 5 shows the measurement results of working example 6.

FIG. 6 shows the measurement results of working example 11.

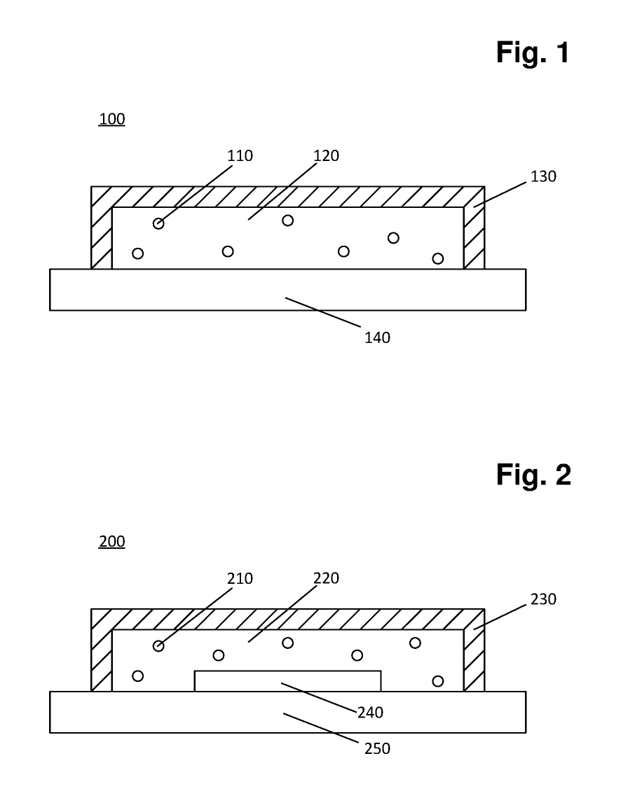

### LIST OF REFERENCE SIGNS IN FIG. 1

100. a color conversion sheet
110. a nanosized fluorescent material
120. a matrix material
130. a barrier layer
140. a substrate (optional)

### LIST OF REFERENCE SIGNS IN FIG. 2

200. an optical device
210. a nanosized fluorescent material
220. a matrix material
230. a barrier layer
240. a light emitting diode element
250. a substrate (optional)

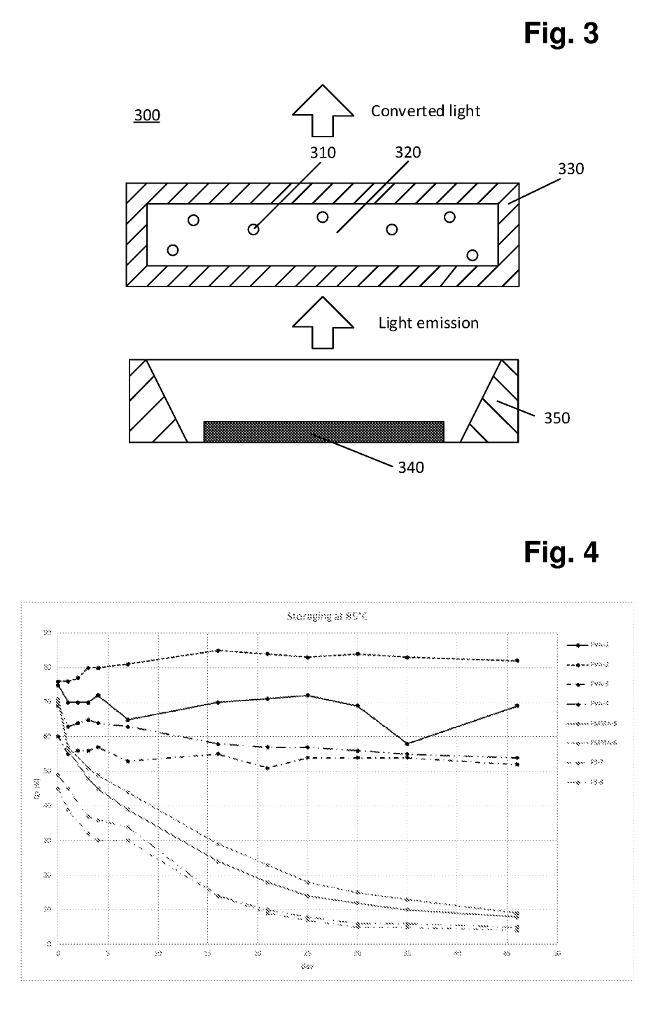

### LIST OF REFERENCE SIGNS IN FIG. 3

300. an optical device
310. a nanosized fluorescent material
320. a matrix material
330. a barrier layer
340. a light emitting diode element
350. a reflector (optional)

### DETAILED DESCRIPTION OF THE INVENTION

According to the present invention, said color conversion sheet (100) comprising at least one nanosized fluorescent material (110), a matrix material (120) and a barrier layer (130), wherein the barrier layer (130) is placed onto the outermost surface of the matrix material (120), is provided by the inventors to solve one or more of the problems 1 to 3.

Nanosized Fluorscent Materials

In a preferred embodiment of the present invention, the nanosized fluorescent material can be selected from the group consisting of nanosized inorganic phosphor materials, quantum sized materials such as quantum dots and or quantum rods, and a combination of any of these.

Without wishing to be bound by theory, it is believed that the nanosized fluorescent material can be used in a higher concentration ratio due to size effect and also may realize sharp vivid color(s) of the color conversion film.

More preferably, the nanosized fluorescent material is a quantum sized material, with furthermore preferably being of a quantum dot material, quantum rod material or a combination of any of these.

According to the present invention, the term “nanosized” means the size in between 1 nm and 900 nm.

Thus, according to the present invention, the nanosized fluorescent material is taken to mean that the fluorescent material which size of the overall diameter is in the range from 1 nm to 900 nm. And in case of the material has elongated shape, the length of the overall structures of the fluorescent material is in the range from 1 nm to 900 nm.

According to the present invention, the term “quantum sized” means the size of the inorganic semiconductor material itself without ligands or another surface modification, which can show the quantum size effect.

Generally, quantum sized material such as quantum dot material, and/or quantum rod materials can emit sharp vivid colored light due to quantum size effect.

According to the present invention, the shape of the quantum sized materials are not particularly limited. Any type of quantum sized materials, such as an elongate shaped, spherical shaped, ellipse shaped, star like shaped, polygon shaped materials can be used in this way preferably.

In a preferred embodiment of the present invention, the quantum sized material can be selected from the group consisting of II-VI, III-V, or IV-VI semiconductors and combinations of any of these.

More preferably, the quantum sized material can be selected from the groups consisting of Cds, CdSe, CdTe, ZnS, ZnSe, ZnTe, ZnO, GaAs, GaP, GaAs, GaSb, HgS, HgSe, HgSe, HgTe, InAs, InP, InSb, AlAs, AlP, AlSb, Cu₂S, Cu₂Se, CuInS2, CuInSe₂, Cu₂(ZnSn)S₄, Cu₂(InGa)S₄, TiO₂ alloys and combination of any of these.

For examples as a quantum dot, CdSeS/ZnS alloyed quantum dots product number 753793, 753777, 753785, 753807, 753750, 753742, 753769, 753866, InP/ZnS quantum dots product number 776769, 776750, 776793, 776777, 776785, PbS core-type quantum dots product number 747017, 747025, 747076, 747084, or CdSe/ZnS alloyed quantum dots product number 754226, 748021, 694592, 694657, 694649, 694630, 694622 from Sigma-Aldrich, can be used preferably as desired.

For examples as a quantum rod, for red emission use, CdSe rods, CdSe dot in CdS rod, ZnSe dot in CdS rod, CdSe/ZnS rods, InP rods, CdSe/CdS rods, ZnSe/CdS rods or combination of any of these, for green emission use, such as CdSe rods, CdSe/ZnS rods, or combination of any of these, and for blue emission use, such as ZnSe, ZnS, ZnSe/ZnS core shell rods, or combination of any of these.

Examples of quantum rod materials have been described in, for example, the laid open international patent application No. WO2010/095140A.

Without wishing to be bound by theory, it is believed that light luminescence from dipole moment of the nanosized fluorescent material having elongated shape may lead higher out-coupling efficiency than the out-coupling efficiency of spherical light emission from quantum dot, organic fluorescent material, and/or organic phosphorescent material, phosphor material.

In other words, it is believed that the long axis of the nanosized fluorescent materials having elongated shape such as quantum rods can align parallel to a substrate surface on average with higher probability and their dipole moments also can align parallel to the substrate surface on average with higher probability.

Thus, according to the present invention, to realize sharp vivid color(s) of the device and better out-coupling effect at the same time, elongated shaped materials such as quantum rod materials are more preferable if desired.

Therefore, in some embodiments of the present invention, the nanosized fluorescent material can be selected from elongated shaped materials such as quantum rod materials to realize better out-coupling effect.

In a preferred embodiment of the invention, the length of the overall structures of the quantum sized material is from 8 nm to 500 nm. More preferably, from 10 nm to 160 nm. The overall diameter of the said elongated shaped materials are in the range from 1 nm to 20 nm. More particularly, it is from 1 nm to 10 nm.

Preferably, the nanosized fluorescent material such as quantum rod and/or quantum dot comprises a surface ligand.

More preferably, according to the present invention, the surface of the quantum sized materials can be over coated with one or more kinds of surface ligands.

Without wishing to be bound by theory it is believed that such a surface ligands may lead to disperse the nanosized fluorescent material in a solvent more easily.

The surface ligands in common use include phosphines and phosphine oxides such as Trioctylphosphine oxide (TOPO), Trioctylphosphine (TOP), and Tributylphosphine (TBP); phosphonic acids such as Dodecylphosphonic acid (DDPA), Tridecylphosphonic acid (TDPA), Octadecylphosphonic acid (ODPA), and Hexylphosphonic acid (HPA); amines such as Dedecyl amine (DDA), Tetradecyl amine (TDA), Hexadecyl amine (HDA), and Octadecyl amine (ODA), thiols such as hexadecane thiol and hexane thiol; mercapto carboxylic acids such as mercapto propionic acid and mercaptoundecanoicacid; and a combination of any of these. And also. Polyethylenimine (PEI) also can be used preferably.

Examples of surface ligands have been described in, for example, the laid open international patent application No. WO 2012/059931A.

Matrix Materials

As a matrix material according to the present invention, any type of publically known transparent matrix materials suitable for optical films can be used.

In a preferred embodiment of the present invention, any transparent polymer matrix material having good thermal stability, low temperature processability in fabrication of the color converting sheet (100), and has long-term durability, can be used.

More preferably, water soluble transparent polymers such as substituted and/or unsubstituted polyvinyl alcohols, and/or polysilazanes such as perhydro polysilazanes and/or organopolysilazanes, can be used in this way.

Even more preferably, as substituted and/or unsubstituted polyvinyl alcohols, polyvinyl alcohol (unsubstituted), cation-substituted polyvinyl alcohols, anion-substituted polyvinyl alcohols, acryl-substituted polyvinyl alcohols, acetoacetyl substituted polyvinyl alcohols (such as Gohsefimer™ Z from Nippon Gohsei), vinyl acetates (such as Exceval™ from Kuraray, Nichigo G-Polymer™ from Nippon Gohsei), silanol substituted polyvinyl alcohols (such as R-1130 series from Kuraray), or a combination of any of these can be used.

Examples of cation-substituted polyvinyl alcohols, anion-substituted polyvinyl alcohols, acryl-substituted polyvinyl alcohols are described in for example, laid open Japanese patent applications No. JPS61-10483A, JPH01-206088A, JPS61-237681A, JPS63-307979A, JPH07-285265A, JPH07-009758A, and JPH08-025795A.

According to the present invention, the average molecular weight M_{w} of a water soluble transparent polymer is not particularly limited.

Preferably, it is in the range from 1,000 to 20,000; with being more preferably in the range from 1,000 to 10,000.

According to the present invention, as polysilazanes, organopolysilazanes can be used more preferably.

For examples of organopolysilazanes, an organopolysilazane having a repeating unit represented by following general formula (I) is suitable.

—(SiR₁R₂NR₃)ₙ— (I)

wherein the formula (I), R₁, R₂, R₃ are, independently of each other, identically or differently, hydrogen atom, alkyl group, alkenyl group, cycloalkyl group, aryl group, alkoxy group, amino group, or a silyl group, and at least one of R₁, R₂, R₃ is a hydrogen atom.

Here, at least one of R₁, R₂, R₃ which is not a hydrogen atom, can be substituted by one or more of halogen atoms, alkyl groups, alkoxy groups, amino groups, silyl groups, and/or alkyl silyl groups.

For examples, fluoro alkyl group, perfluoro alkyl group, silyl alkyl group, trisilyl alkyl group, alkylsilylalkyl group, trialkyl silyl group, alkoxy silyl alkyl group, fluoro alkoxy group, silyl alkoxy group, alkyl amino group, dialkyl amino group, alkyl amino alkyl group, alkyl silyl group, dialkyl silyl group, alkoxy silyl group, dialkoxy silyl group, trialkoxy silyl group can be used.

Examples of organopolysilazanes and perhydropolysilazanes are described in, for example, the laid open Japanese patent applications JP 2015-115369A, and JP 2014-77082A.

According to the present invention, the average molecular weight M_{w} of a polysilazane is not particularly limited.

Preferably, it is in the range from 1,000 to 20,000; with being more preferably in the range from 1,000 to 10,000.

According to the present invention, the average molecular weight M_{w} is determined by means of GPC (=gel permeation chromatography) against an internal polystyrene standard.

Barrier Layer

According to the present invention, polysilazanes, especially, any perhydropolysilazane (hereafter “PHPS”) can be used preferably to fabricate a barrier layer (130).

Without wishing to be bound by theory, it is believed that perhzdropolzsilayanes may realize wet fabrication process instead of vapor deposition process and can reduce fabrication damage of nanosized fluorescent material in the process, and a barrier layer made from PHPS has less defects in the layer.

Thus, in one embodiment of the present invention, the barrier layer (130) is a layer obtained from PHPS.

According to the present invention, in some embodiments, the barrier layer (130) comprises a gradient structure comprised of an outermost part and subsequent part in the layer, wherein the outermost part consists of silicon nitride.

In a preferred embodiment of the present invention, the gradient is a hydrogen content.

More preferably, the outermost part of the gradient structure to the matrix material (120) comprises higher amount of hydrogen than the opposite side of the gradient structure to the barrier layer (130).

Without wishing to be bound by theory, it is believed that the barrier layer fabricated by using PHPS solution may have lower refractive index than the refractive index of a barrier layer fabricated by any vapor deposition method (such as CVD), and may lead better refractive index matching to the matrix materials of the present invention.

In some embodiments of the present invention, the barrier layer (130) has the refractive index in the range from 1.38 to 1.85.

In a preferred embodiment of the present invention, the barrier layer (130) has the refractive index in the range from 1.45 to 1.60.

More preferably, the barrier layer (130) is fabricated from PHPS and has the refractive index in the range from 1.38 to 1.85; with being more preferably in the range from 1.45 to 1.60.

By changing the drying condition of the PHPS layer and by controlling vacuum ultraviolet (hereafter “VUV”) light irradiation condition, the refractive index value of the barrier layer (130) can be controlled.

According to the present invention, the term “vacuum ultraviolet” means an ultraviolet light having a peak wavelength in the region from 190 nm to 80 nm.

Polymerization Initiator

Turning to the other components of the present invention, the matrix material and/or the PHPS layer of the present invention can optionally contain another one or more of additives if necessary. Such as a polymerization initiator. Generally, there are two kinds of polymerization initiators which can be used in the present invention: one is a polymerization initiator generating an acid, base, or radical when exposed to radiation, and the other is a polymerization initiator generating an acid, base or radical when exposed to heat.

The polymerization initiator adoptable in the present is, for example, a photo acid-generator, which decomposes when exposed to radiation and releases an acid serving as an active substance for photo-curing the composition; a photo radical—generator, which releases a radical; a photo base-generator, which releases a base; a heat acid-generator, which decomposes when exposed to heat and releases an acid serving as an active substance for heat-curing the composition; a heat radical—generator, which releases a radical; and a heat base-generator, which releases a base. Examples of the radiation include visible light, UV rays, such as VUV rays, IR rays, X-rays, electron beams, α-rays and γ-rays.

In a preferred embodiment of the present invention, the amount of the polymerization initiator is in the range from 0.001 to 10 weight parts, more preferably 0.01 to 5 weight parts, based on 100 weight parts of the matrix material or PHPS material. More than 0.001 weight part is preferable to obtain the effect of the initiator. On the other hand, less than 10 weight parts of the polymerization initiator is preferable to prevent cracks of the fabricated color conversion sheet (100), or to prevent coloring of the fabricated sheet caused by decomposition of the initiator.

Examples of the above photo acid-generator include diazomethane compounds, diphenyliodonium salts, triphenylsulfonium salts, sulfonium salts, ammonium salts, phosphonium salts and sulfonamide compounds.

The structures of those photo acid-generators can be represented by the formula (A):

R⁺X⁻ (A).

Wherein the formula (A), R⁺ is hydrogen or an organic ion modified by carbon atoms or other hetero atoms provided that the organic ion is selected from the group consisting of alkyl groups, aryl groups, alkenyl groups, acyl groups and alkoxy groups. For example, R⁺ is diphenyliodonium ion or triphenylsulfonium ion.

Further, X⁻ is preferably a counter ion represented by any of the following formulas:

SbY₆⁻,

AsY₆⁻,

R^{a}ₚPY₆₋ₚ⁻,

R^{a}_{q}BY_{4-q}⁻,

R^{a}_{q}GaY_{4-q}⁻,

R^{a}SO₃⁻,

(R^{a}SO₂)₃C⁻,

(R^{a}SO₂)₂N⁻,

R^{a}COO⁻, and

SCN⁻

in which
Y is a halogen atom,
R^{a} is an alkyl group of 1 to 20 carbon atoms or an aryl group of 6 to 20 carbon atoms provided that each group is substituted with a substituent group selected from the group consisting of fluorine, nitro group and cyano group,
R^{b} is hydrogen or an alkyl group of 1 to 8 carbon atoms,
P is a number of 0 to 6, and
q is a number of 0 to 4.

Concrete examples of the counter ion (x⁻) include: BF₄, (C₆F₅)₄B⁻, ((CF₃)₂C₆H₃)₄B⁻, PF₆⁻, (CF₃CF₂)₃PF₃⁻, SbF₆⁻, (C₆F₅)₄Ga⁻, ((CF₃)₂C₆H₃)₄Ga⁻, SCN⁻, (CF₃SO₂)₃C⁻, (CF₃SO₂)₂N⁻, formate ion, acetate ion, trifluoromethanesulfonate ion, nonafluorobutanesulfonate ion, methane-sulfonate ion, butanesulfonate ion, benzenesulfonate ion, p-toluenesulfonate ion, and sulfonate ion.

Among the photo acid-generators usable in the present invention, those generating sulfonic acids or boric acids are particularly preferred. Examples thereof include tricumyliodonium teterakis(pentafluorophenyl)-borate (PHOTOINITIATOR2074 [trademark], manufactured by Rhodorsil), diphenyliodonium tetra(perfluorophenyl)borate, and a compound having sulfonium ion and pentafluoroborate ion as the cation and anion moieties, respectively. Further, examples of the photo acid-generators also include triphenylsulfonium trifluoromethanesulfonate, triphenylsulfonium camphor-sulfonate, triphenylsulfonium tetra(perfluorophenyl)borate, 4-acetoxyphenyldimethylsulfonium hexafluoroarsenate, 1-(4-n-butoxynaphthalene-1-yl)tetrahydrothiophenium trifluoromethanesulfonate, 1-(4,7-dibutoxy-1-naphthalenyl)tetrahydrothiophenium trifluoromethanesulfonate, diphenyliodonium trifluoromethanesulfonate, and diphenyliodonium hexafluoroarsenate. Furthermore, it is still also possible to adopt photo acid-generators represented by the following formulas:

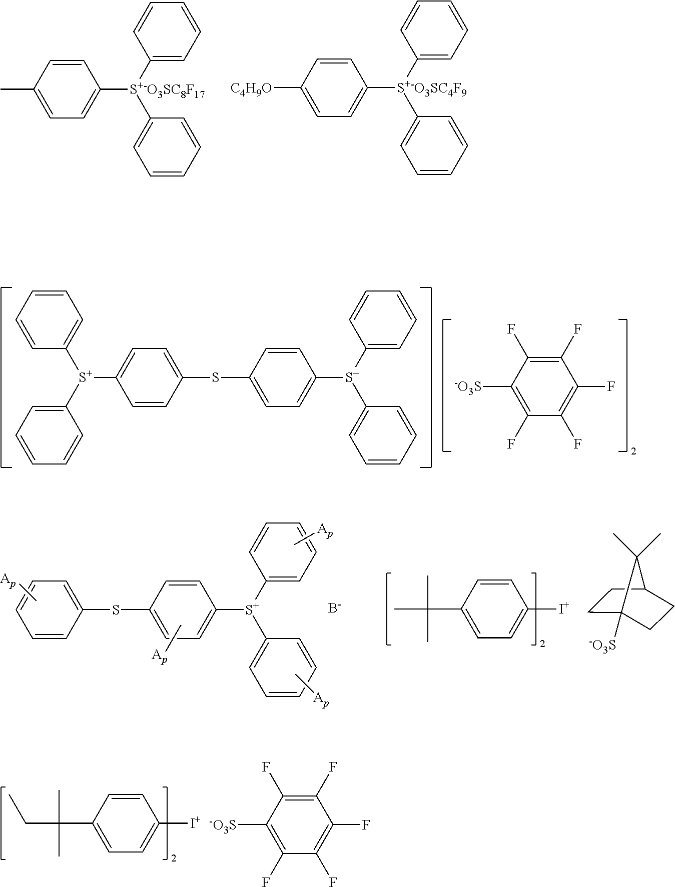

in which
each A is independently a substituent group selected from the group consisting of an alkyl group of 1 to 20 carbon atoms, an alkoxy group of 1 to 20 carbon atoms, an aryl group of 6 to 20 carbon atoms, an alkylcarbonyl group of 1 to 20 carbon atoms, an arylcarbonyl group of 6 to 20 carbon atoms, hydroxyl group, and amino group;
each p is independently an integer of 0 to 5; and
B⁻ is a fluorinated alkylsulfonate group, a fluorinated arylsulfonate group, a fluorinated alkylborate group, an alkylsulfonate group or an arylsulfonate group.

It is also possible to use photo acid-generators in which the cations and anions in the above formulas are exchanged each other or combined with various other cations and anions described above. For example, any one of the sulfonium ions represented by the above formulas can be combined with tetra(perfluorophenyl)borate ion, and also any one of the iodonium ions represented by the above formulas can be combined with tetra(per-fluorophenyl)borate ion. Those can be still also employed as the photo acid-generators.

The heat acid-generator is, for example, a salt or ester capable of generating an organic acid. Examples thereof include: various aliphatic sulfonic acids and salts thereof; various aliphatic carboxylic acids, such as, citric acid, acetic acid and maleic acid, and salts thereof; various aromatic carboxylic acids, such as, benzoic acid and phthalic acid, and salts thereof; aromatic sulfonic acids and ammonium salts thereof; various amine salts; aromatic diazonium salts; and phosphonic acid and salts thereof. Among the heat acid-generators usable in the present invention, salts of organic acids and organic bases are preferred, and further preferred are salts of sulfonic acids and organic bases.

Examples of the preferred heat acid-generators containing sulfonate ions include p-toluenesulfonates, benzenesulfonates, p-dodecylbenzenesulfonates, 1,4-naphthalenedisulfonates, and methanesulfonates.

Examples of the photo radical-generator include azo compounds, peroxides, acyl phosphine oxides, alkyl phenons, oxime esters, and titanocenes.

According to the present invention, as the photo radical-generator, acyl phosphine oxides, alkyl phenons, oxime esters, or a combination of any of these are more preferable. For examples, 2,2-dimethxye-1,2-diphenylethane-1-on, 1-hydroxy-cyclohexylphenylketone, 2-hydroxy-2-methyl-1-phenylpropan-1-on, 1-[4-(2-hydroxyethoxy)phenyl]-2-hydroxy-2-methyl-1-propane-1-on, 2-hydroxy-1-{4-[4-(2-hydroxy-2-methylpropionyl)benzyl]phenyl}-2-methylpropane-1-on, 2-methyl-1-(4-methylthiophenyl)-2-morpholinopropane-1-on, 2-benzyl-2-dimethylamino-1-(4-morpholinophenyl)-1-butanone, 2-(dimethylamino)-2-[(4-methylphenon)methyl]-1-[4-(4-morpholinyl)phenyl]-1-butanone, 2,4,6-trimethylbenzoyl-diphenylphosphine oxide, bis(2,4,6-trimethylbenzoyl)phenylphosphine oxide, 1,2-octanedione 1-[4-(phenylthio)-2-(o-benzoyl oxime)], ethanone 1-[9-ethyl-6-(2-methylbenzoyl)-9H-carbazole-3-yl]-1-(o-acetyl oxime) or a combination of any of these can be used preferably.

As the examples of the heat radical-generator, 2,2′ azobis(2-methylvaleronitrile), 2,2′-azobis(dimethylvaleronitrile) or a combination of any of these can be used preferably.

Examples of the photo base-generator include multi-substituted amide compounds having amide groups, lactams, imide compounds, and compounds having those structures.

Examples of the above heat base-generator include: imidazole derivatives, such as, N-(2-nitrobenzyloxycarbonyl)imidazole, N-(3-nitrobenzyloxycarbonyl)imidazole, N-(4-nitrobenzyloxycarbonyl)imidazole, N-(5-methyl-2-nitrobenzyloxycarbonyl)imidazole, and N-(4-chloro-2-nitro-benzyloxycarbonyl)imidazole; 1,8-diazabicyclo(5,4,0)undecene-7, tertiary amines, quaternary ammonium salts, and mixture thereof. Those base-generators as well as the acid-generators and/or radical—generators can be used singly or in mixture.

According to the present invention, a polymerization initiator generating an acid, base, or radical when exposed to radiation can be used preferably.

Thus, in a preferred embodiment of the present invention, the polymerization initiator can be selected from the group consisting of a photo radical-generator, photo base-generator, photo acid-generator, and a combination of any of these.

More preferably, the polymerization initiator can be a photo radical-generator.

Other Additives

The matrix material and/or polysilazane for a barrier layer of the present invention may further contain other additives, if necessary. Examples of the additives include adhesion enhancer, polymerization inhibitor, surfactant and sensitizer.

As the adhesion enhancer, imidazoles and silane coupling agents are preferably adopted. Examples of the imidazoles include 2-hydroxybenzimidazole, 2-hydroxyethylbenzimidazole, benzimidazole, 2-hydroxyimidazole, imidazole, 2-mercaptoimidazole, and 2-aminoimidazole. Among them, particularly preferred are 2-hydroxybenzimidazole, benzimidazole, 2-hydroxyimidazole and imidazole.

As the silane coupling agents, known compounds, such as, epoxy-silane coupling agents, amino-silane coupling agents and mercapto-silane coupling agents, can be preferably adopted. Examples thereof include 3-glycidoxypropyltrimethoxysilane, 3-glycidoxypropyltriethoxysilane, N-2-(aminoethyl)-3-aminopropyltrimethoxysilane, N-2-(aminoethyl)-3-aminopropyltriethoxysilane, 3-aminopropyltrimethoxysilane, 3-aminopropyltriethoxysilane, 3-uridopropyltrimethoxysilane, 3-chloropropyltrimethoxysilane, 3-mercaptopropyltrimethoxysilane, and 3-isocyanatepropyltrimethoxysilane. Those can be used singly or in combination of two or more. The amount thereof is preferably 0.05 to 15 weight parts based on 100 weight parts of the matrix material and/or polysilazane for a barrier layer of the present invention.

It is also possible to employ a silane or siloxane compound having an acidic group as the silane coupling agent. Examples of the acidic group include carboxyl group, an acid anhydride group, and phenolic hydroxyl group. If having a monobasic acid group such as carboxyl or phenolic hydroxyl group, the compound is preferably a single silicon-containing compound having two or more acidic groups.

Examples of the above silane coupling agent include compounds represented by the following formula (B):

XₙSi(OR⁴)₄₋ₙ (B)

and polymers having polymerization units derived from them. Those polymers may comprise plural kinds of units different in X or R³ in combination.

In the above formula, R⁴ is a hydrocarbon group, such as, an alkyl group, preferably having 1 to 10 C atoms. Examples thereof include methyl, ethyl, n-propyl, iso-propyl and n-butyl groups. The formula (A) contains plural R⁴s, which may be the same or different from each other.

In the above formula, X includes an acidic group, such as, thiol, phosphonium, borate, carboxyl, phenol, peroxide, nitro, cyano, sulfo or alcohol group. The acidic group may be protected with a protective group, such as, acetyl, aryl, amyl, benzyl, methoxymethyl, mesyl, tolyl, trimethoxysilyl, triethoxysilyl, triisopropylsilyl or trityl group. Further, X may be an acid anhydride group.

Among the above, R⁴ and X are preferably methyl group and a carboxylic acid anhydride group, respectively. For example, an acid anhydride group-containing silicone is preferred. Concrete examples thereof are a compound represented by the following formula (B-1) (X-12-967C [trademark], manufactured by Shin-Etsu Chemical Co., Ltd.) and a silicon-containing polymer, such as silicone, having a structure corresponding the formula at the terminal or in the side chain and having a weight average molecular weight of 1000 or less. Also preferred is a dimethyl silicone having a weight average molecular weight of 4000 or less and having a terminal modified with an acidic group, such as, thiol, phosphonium, borate, carboxyl, phenol, peroxide, nitro, cyano or sulfo group. Examples thereof include compounds represented by the following formulas (B-2) and (B-3) (X-22-2290AS and X-22-1821 [trademark], manufactured by Shin-Etsu Chemical Co., Ltd.).

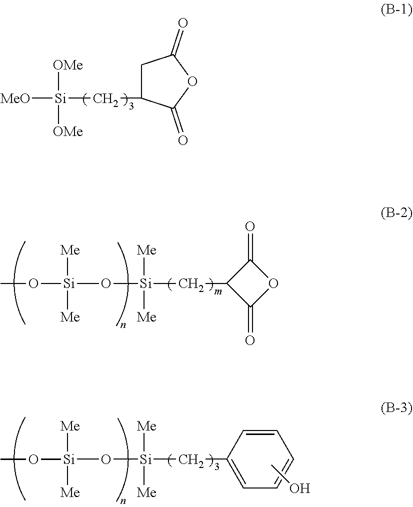

If the silane coupling agent contains a silicone structure and has too large a molecular weight, it has poor compatibility with the composition. Consequently, the coating is dissolved in a developer so insufficiently that reactive groups may remain in the coating. This may cause problems in that, for example, the coating cannot have enough chemical resistance against post-processes. In view of that, the silicon-containing compound has a weight average molecular weight of preferably 5000 or less, more preferably 1000 to 4000. Further, if the acidic group-containing silane or siloxane compound is employed as the silane coupling agent, the amount thereof is preferably 0.01 to 15 weight parts based on 100 weight parts of the matrix material and/or polysilazane for a barrier layer of the present invention.

As the polymerization inhibitor, nitrone derivatives, nitroxide radical derivatives and hydroquinone derivatives, such as, hydroquinone, methylhydroquinone and butyllhydroquinine, can be incorporated. Those can be used singly or in combination of two or more. The amount thereof is preferably 0.1 to 10 weight parts based on 100 weight parts of the matrix material and/or polysilazane for a barrier layer of the present invention.

Examples of the defoaming agent include: alcohols (C₁ to C₁₈); higher fatty acids, such as, oleic acid and stearic acid; higher fatty acid esters, such as, glycerin monolaurate; polyethers, such as, polyethylenglycol (PEG) (Mn: 200 to 10000) and polypropyleneglycol (Mn: 200 to 10000); silicone compounds, such as, dimethyl silicone oil, alkyl-modified silicone oil and fluoro-silicone oil; and organic siloxane surfactants described below in detail. Those can be used singly or in combination of two or more. The amount thereof is preferably 0.1 to 3 weight parts based on 100 weight parts of the matrix material and/or polysilazane for a barrier layer of the present invention.

If necessary, the matrix material and/or polysilazane for a barrier layer of the present invention can further contain a surfactant, which is incorporated with the aim of improving coatability, developability and the like. The surfactants usable in the present invention are, for example, nonionic, anionic and amphoteric surfactants.

Examples of the nonionic surfactants include: polyoxyethylene alkyl ethers, such as, polyoxyethylene lauryl ether, polyoxyethylene oleyl ether and polyoxyethylene cetyl ether; polyoxyethylene fatty acid diethers; polyoxyethylene fatty acid monoethers; polyoxyethylene-polyoxypropylene block polymer; acetylene alcohol; acetylene glycol derivatives, such as, acetylene glycol, polyethoxyate of acetylene alcohol, and polyethoxyate of acetylene glycol; silicon-containing surfactants, such as, Fluorad ([trademark], manufactured by Sumitomo 3M Limited), MEGAFAC ([trademark], manufactured by DIC Corporation), and Surufuron ([trademark], manufactured by Asahi Glass Co., Ltd.); and organic siloxane surfactants, such as, KP341 ([trademark], manufactured by Shin-Etsu Chemical Co., Ltd.). Examples of the above acetylene glycols include: 3-methyl-1-butyne-3-ol, 3-methyl-1-pentyne-3-ol, 3,6-dimethyl-4-octyne-3,6-diol, 2,4,7,9-tetramethyl-5-decyne-4,7-diol, 3,5-dimethyl-1-hexyne-3-ol, 2,5-dimethyl-3-hexyne-2,5-diol, and 2,5-dimethyl-2,5-hexanediol.

Examples of the anionic surfactants include: ammonium salts and organic amine salts of alkyldiphenylether disulfonic acids, ammonium salts and organic amine salts of alkyldiphenylether sulfonic acids, ammonium salts and organic amine salts of alkylbenzenesulfonic acids, ammonium salts and organic amine salts of polyoxyethylenealkylether sulfuric acids, and ammonium salts and organic amine salts of alkylsulfuric acids.

Further, examples of the amphoteric surfactants include 2-alkyl-N-carboxymethyl-N-hydroxyethyl imidazolium betaine, and laurylic acid amidopropyl hydroxy sulfone betaine.

Those surfactants can be used singly or in combination of two or more. The amount thereof is normally 50 to 2000 ppm, preferably 100 to 1000 ppm based on the photosensitive composition of the present invention.

According to necessity, a sensitizer can be incorporated into the matrix material and/or polysilazane for a barrier layer of the present invention. Examples of the sensitizer preferably used in the composition of the present invention include Coumarin, ketocoumarin, derivatives thereof, thiopyrylium salts, and acetophenone. Specifically, concrete examples thereof include: sensitizing dyes, such as, p-bis(o-methylstryl)benzene, 7-dimethylamino-4-methylquinolone-2,7-amino-4-methylcoumarin, 4,6-dimethyl-7-ethylaminocoumarin, 2-(p-dimethylaminostryl)pyridylmethyl iodide, 7-diethylaminocoumarin, 7-diethylamino-4-methylcoumarin, 2,3,5,6-1H,4H-tetrahydro-8-methylquinolidino-<9,9a,1-gh>coumarin, 7-diethylamino-4-trifluoromethylcoumarin, 7-dimethylamino-4-trifluoromethylcoumarin, 7-amino-4-trifluoromethylcoumarin, 2,3,5,6-1H,4H-tetrahydroquinolidino<9,9a,1-gh>Coumarin, 7-ethylamino-6-methyl-4-trifluoromethylcoumarin, 7-ethylamino-4-trifluoromethylcoumarin, 2,3,5,6-1H,4H-tetrahydro-9-carboethoxyquinolidino-<9,9a,1-gh>coumarin, 3-(2′-N-methylbenzimidazolyl)-7-N,N-diethylaminocoumarin, N-methyl-4-trifluoromethylpiperidino-<3,2-g>Coumarin, 2-(p-dimethylaminostryl)benzo-thiazolylethyl iodide, 3-(2′-benzimidazolyl)-7-N,N-diethylaminocoumarin, 3-(2′-benzothiazolyl)-7-N,N-diethylaminocoumarin, and pyrylium or thiopyrylium salts represented by the following formula. The sensitizing dye makes it possible to carry out patterning by use of inexpensive light sources, such as, a high-pressure mercury lamp (360 to 430 nm). The amount thereof is preferably 0.05 to 15 weight parts, more preferably 0.1 to 10 weight parts based on 100 weight parts of the matrix material and/or polysilazane for a barrier layer of the present invention.

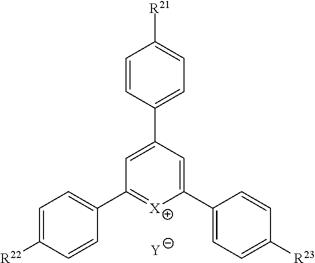

| X | R₁ | R₂ | R₃ | Y |
|---|---|---|---|---|
| S | OC₄H₉ | H | H | BF₄ |
| S | OC₄H₉ | OCH₃ | OCH₃ | BF₄ |
| S | H | OCH₃ | OCH₃ | BF₄ |
| S | N(CH₃)₂ | H | H | ClO₂ |
| O | OC₄H₉ | H | H | SbF₆ |

As the sensitizer, it is also possible to adopt a compound having an anthracene skeleton. Concrete examples thereof include compounds represented by the following formula (C):

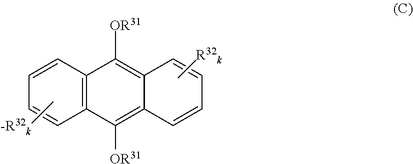

in which

each R³¹ is independently a substituent group selected from the group consisting of alkyl groups, aralkyl groups, aryl groups, hydroxyalkyl groups, alkoxyalkyl groups, glycidyl groups and halogenated alkyl groups;

each R³² is independently a substituent group selected from the group consisting of hydrogen, alkyl groups, alkoxy groups, halogen atoms, nitro groups, sulfonic acid groups, hydroxyl group, amino groups, and carboalkoxy groups; and

each k is independently an integer of 0 and 1 to 4.

The sensitizers having anthracene skeletons are disclosed in, for example, Patent documents 3 and 4. When the sensitizer having an anthracene skeleton is added, the amount thereof is preferably 0.01 to 5 weight parts based on 100 weight parts of the matrix material and/or polysilazane for a barrier layer of the present invention.

Further, if necessary, a stabilizer can be also added into the matrix material and/or polysilazane for a barrier layer of the present invention. The stabilizer can be freely selected from those generally known. However, in the present invention, aromatic amines are preferred because they have high effect on stabilization. Among those aromatic amines, preferred are pyridine derivatives and particularly preferred are pyridine derivatives having bulky substituent groups at 2- and 6-positions. Concrete examples thereof are as follows:

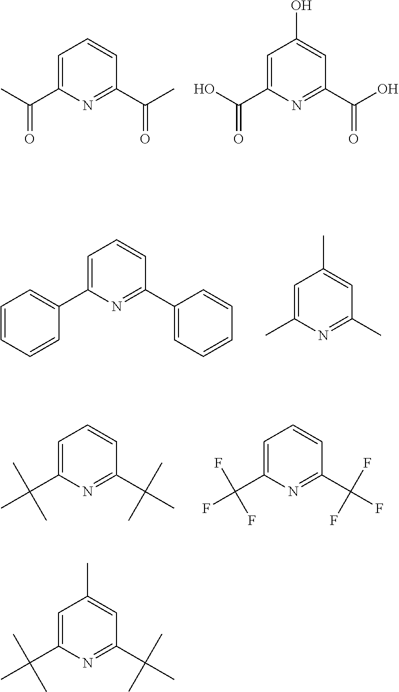

In some embodiments of the present invention, only a polysilazane for a barrier layer of the present invention may comprise the one or more of additives, if necessary. For example to avoid unnecessary chemical reaction between nanosized fluorescent material and one or more of additives.

Color Conversion Sheet (100)

According to the present invention, the term “sheet” includes “layer” and “film” like structures.

In some embodiments of the present invention, optionally, the color conversion sheet (100) can comprise a transparent substrate.

In general, transparent substrate can be flexible, semi-rigid or rigid. Publically known transparent substrate suitable for optical devices can be used as desired.

Preferably, as a transparent substrate, a transparent polymer substrate, glass substrate, thin glass substrate stacked on a transparent polymer film, transparent metal oxides (for example, oxide silicone, oxide aluminum, oxide titanium), can be used.

A transparent polymer substrate can be made from polyethylene, ethylene-vinyl acetate copolymer, ethylene-vinyl alcohol copolymer, polypropylene, polystyrene, polymethyl methacrylate, polyvinylchloride, polyvinyl alcohol, polyvinylvutyral, nylon, polyether ether ketone, polysulfone, polyether sulfone, tetrafluoroethylene-erfluoroalkylvinyl ether copolymer, polyvinyl fluoride, tetraflyoroethylene ethylene copolymer, tetrafluoroethylene hexafluoro polymer copolymer, or a combination of any of these.

The term “transparent” means at least around 60% of incident light transmittal at the thickness used in an optical device and at a wavelength or a range of wavelength used during operation of an optical device. Preferably, it is over 70%, more preferably, over 75%, most preferably, it is over 80%.

In some embodiments of the present invention, the color conversion sheet (100) can further comprises UV cut layer to reduce/prevent any UV damage of the nanosized fluorescent material (110) in the color conversion layer.

Preferably, the UV cut layer is placed in between the barrier layer (130) and the matrix material (120) to prevent UV damage of the nanosized fluorescent material (110) effectively.

According to the present invention, any type of transparent UV cut layer can be used preferably.

Publically known transparent UV cut filters, films can also be used as a UV cut layer of the invention.

According to the present invention, the color conversion sheet (100) can be a homogeneous color conversion sheet or can comprise first and second sub color areas (120), in which at least first sub color area emits light having longer peak wavelength than the second sub color areas when it is illuminated by light source.

Thus, in one embodiment of the present invention, the color conversion sheet (100) can be a homogeneous color conversion sheet.

In some embodiments of the present invention, the color conversion sheet (100) can comprise red sub color areas, green sub color areas and blue sub color areas.

In some embodiments of the present invention, the color conversion sheet (100) can mainly consist of red sub color areas, green sub color areas and blue sub color areas, if necessary.

In some embodiments of the present invention, in case of blue light emitting light element such as blue LED(s) is used, the blue sub color areas can be made without blue nanosized fluorescent material (110).

In some embodiments of the present invention, optionally, the color conversion sheet (100) can further comprises a black matrix (hereafter “BM”).

A material for the BM is not particularly limited. Well known materials, especially well known BM materials for color filters can be used preferably as desired. Such as black dye dispersed polymer composition, like described in JP 2008-260927A and WO 2013/031753A.

Fabrication method of the BM is not particularly limited, well known techniques can be used in this way. Such as, direct screen printing, photolithography, vapor deposition with mask.

Optical Devices

In another aspect, the invention further relates to an optical device (200) comprising the color conversion sheet (100).

In a preferred embodiment of the present invention, the optical device (200) can embrace a light source.

According to the present invention, the type of light source in the optical device is not particularly limited.

Preferably, UV or blue single color light source, such as LED, CCFL, EL, or a combination of any of these, can be used.

For the purpose of the present invention, the term “blue” is taken to mean a light wavelength between 380 nm and 515 nm. Preferably, “blue” is between 430 nm and 490 nm. More preferably, it is between 450 nm and 470 nm.

More preferably, the light source emits light having peak wavelength in a blue light region, such as blue LED, CCFL, EL, or a combination of any of these, can be used.

In one embodiment of the present invention, optionally, the light source can further embrace a light guiding plate such as a light reflector (350) to increase light uniformity and/or to increase light-use efficiency from the light source.

In another aspect, the invention also relates to an optical device (200), wherein the optical device (200) comprises at least one nanosized fluorescent material (210), a matrix material (220), a barrier layer (230), and a light emitting diode element (240), wherein the barrier layer (230) is placed onto the outermost surface of the matrix material (220).

In some embodiments of the present invention, optionally, the optical device (200) can comprise a substrate (250).

In general, the substrate can be flexible, semi-rigid or rigid.

According to the present invention, publically known substrates suitable for optical devices, such as transparent substrates, metal substrates, silicon substrates, can be used as desired.

In a preferred embodiment of the present invention, a transparent substrate can be used.

Preferably, as a transparent substrate, a transparent polymer substrate, glass substrate, thin glass substrate stacked on a transparent polymer film, transparent metal oxides (for example, oxide silicone, oxide aluminum, oxide titanium), can be used.

A transparent polymer substrate can be made from polyethylene, ethylene-vinyl acetate copolymer, ethylene-vinyl alcohol copolymer, polypropylene, polystyrene, polymethyl methacrylate, polyvinylchloride, polyvinyl alcohol, polyvinylvutyral, nylon, polyether ether ketone, polysulfone, polyether sulfone, tetrafluoroethylene-erfluoroalkylvinyl ether copolymer, polyvinyl fluoride, tetraflyoroethylene ethylene copolymer, tetrafluoroethylene hexafluoro polymer copolymer, or a combination of any of these.

In one embodiment of the present invention, the optical device (200) can further comprise a light modulator.

In a preferred embodiment of the present invention, the light modulator can be selected from the group consisting of liquid crystal element, Micro Electro Mechanical Systems (here in after “MEMS”), electro wetting element, and electrophoretic element.

In the case of the light modulator is a liquid crystal element, any type of liquid crystal element can be used in this way. For example, twisted nematic mode, vertical alignment mode, IPS mode, guest host mode liquid crystal element, which commonly used for LCDs are preferable.

Furthermore, according to the present invention, normally black TN mode liquid crystal element is also applicable as the light modulator.

Generally, without wishing to be bound by theory, it is said that the normally black TN mode can realize higher contrast ratio but fabrication process is complicated due to the different cell gap in each color pixel to keep good white balance.

According to the present invention, there is no need to change the cell gap of normally black TN mode LC element at each pixel.

Because, according to the present invention, a single color excitation light source can be used preferably in the combination with the color converting sheet (100). Such as, as a single color excitation light source, UV LED, blue LED.

In that case, the light source emits light having one peak wavelength region and the intensity of the excitation light from the light source can be controlled by the normally black TN mode LC layer having same cell gap at each pixel, then, the excitation light goes into the color conversion sheet (100) and converted into longer wavelength.

In some embodiments of the present invention, the light modulator is placed on the light extraction side of the color conversion sheet (100).

In some embodiments of the present invention, the light modulator is placed in between the light source and the color conversion sheet (100).

According to the present invention, in some embodiments, the surface of the color conversion sheet (100), which opposite side from the light source, can have nano-meter scale structures instead of the sheet having nano-meter scale structures. Without wishing to be bound by theory, it is believed that the nano-meter scale structures may prevent light loss by the total reflection.

In some embodiments of the present invention, optionally, the light source can be switchable.

According to the present invention, the term “switchable” means that the light can selectively be switched on or off.

In a preferred embodiment of the present invention, the switchable light source can be selected from the group consisting of, active matrix EL, passive matrix EL, a plural of LEDs and a combination of any of these.

Thus, in one embodiment of the present invention, the optical device further comprises a light emitting diode element (240).

In a preferred embodiment of the present invention, the optical device can be a light emitting diode device comprising the color conversion sheet (100), and a light emitting diode element (240).

In some embodiments of the present invention, optionally, the optical device (200) can further include a color filter layer. According to the present invention, as the color filter, any type of publically known color filter including red, green and blue sub color region for optical devices, such as LCD color filter, can be used in this way preferably.

In a preferred embodiment of the present invention, the red sub color region of the color filter can be transparent to light wavelength at least in between 610 and 640 nm, and the green sub color region of the color filter is transparent to the light wavelength at least in between 515 and 550 nm.

In a preferred embodiment of the present invention, the optical device (200) can be selected from the group consisting of light emitting diode device, a liquid crystal display, electro-luminescent displays, MEMS display, electro wetting display, and electrophoretic display.

More preferably, the optical device (200) can be a light emitting diode device, or a liquid crystal display, such as twisted nematic liquid crystal display, vertical alignment mode liquid crystal display, IPS mode liquid crystal display, guest host mode liquid crystal display, or the normally black TN mode liquid crystal display.

Examples of optical devices have been described in, for example, WO 2010/095140 A2 and WO 2012/059931 A1.

Fabrication Methods

In another aspect, the present invention furthermore relates to method for preparing the color conversion sheet (100), wherein the method comprises following steps (a) and (c) in this sequence;
(a) providing at least one nanosized fluorescent material (110), and a matrix material (120) onto a substrate,
(b) providing perhydropolysilazane solution onto the surface of the matrix material, and
(c) exposing the perhydropolysilazane to vacuum ultraviolet light.
In a preferred embodiment of the present invention, wherein the method further comprises step (d) after step (b) and before step (c);
(d) drying the perhydropolysilazane solution.

In some embodiment of the present invention, the heat temperature of the drying step (d) can be in the range from 40° C. to 200° C. In a preferred embodiment of the present invention, the baking temperature in baking step is in the range from 70° C. to 180° C. More preferably, it is in the range from 80° C. to 160° C. Even more preferably, it is in the range from 100° C. to 140° C.

The drying time is not particularly restricted, preferably it is from 30 seconds to 24 hours, more preferably from 60 seconds to 10 hours.

Coating Step

According to the present invention, to provide at least one nanosized fluorescent material (110), and a matrix material (120) onto a substrate, and/or providing perhydropolysilazane solution onto the surface of the matrix material, any type of publically known coating method can be used preferably. For examples, inkjet printing, immersion coating, gravure coating, roll coating, bar coating, brush coating, spray coating, doctor coating, flow coating, spin coating, and slit coating.

The substrate to be coated with providing perhydropolysilazane solution onto the surface of the matrix material in step (a) is also not particularly limited, and can be properly selected from, for example, a silicon substrate, a glass substrate, or a polymer film. And the substrate can be solid or flexible as described on page 28 and 29 in “—Color conversion sheet (100)”.

Solvents

According to the present invention, a wide variety of publically known solvents can be used preferably in fabrication. There are no particular restrictions on the solvent as long as it can homogeneously dissolve or disperse the above a matrix material or polysilazanes for a barrier layer, the polymerization initiator, and additives incorporated optionally.

In a preferred embodiment of the present invention, the solvent can be selected from the group consisting of ethylene glycol monoalkyl ethers, such as, ethylene glycol monomethyl ether, ethylene glycol monoethyl ether, ethylene glycol monopropyl ether, and ethylene glycol monobutyl ether; diethylene glycol dialkyl ethers, such as, diethylene glycol dimethyl ether, diethylene glycol diethyl ether, diethylene glycol dipropyl ether, and diethylene glycol dibutyl ether; ethylene glycol alkyl ether acetates, such as, methyl cellosolve acetate and ethyl cellosolve acetate; propylene glycol alkyl ether acetates, such as, propylene glycol monomethyl ether acetate (PGMEA), propylene glycol monoethyl ether acetate, and propylene glycol monopropyl ether acetate; aromatic hydrocarbons, such as, benzene, toluene and xylene; ketones, such as, methyl ethyl ketone, acetone, methyl amyl ketone, methyl isobutyl ketone, and cyclohexanone; alcohols, such as, ethanol, propanol, butanol, hexanol, cyclohexanol, ethylene glycol, and glycerin; esters, such as, ethyl 3-ethoxypropionate, methyl 3-methoxypropionate and ethyl lactate; and cyclic asters, such as, γ-butyrolactone; heptane; dibutylether; or purified water. Those solvents are used singly or in combination of two or more, and the amount thereof depends on the coating method and the thickness of the coating.

The amount of the solvent in the photosensitive composition can be freely controlled according to the method of coating the composition. For example, if the composition is to be spray-coated, it can contain the solvent in an amount of 90 wt. % or more. Further, if a slit-coating method, which is often adopted in coating a large substrate, is more to be carried out, the content of the solvent is preferably 60 wt. % or more, more preferably 70 wt. % or more.

Prebaking Step

In a preferred embodiment of the present invention, optionally, after step (a), prebaking (preheating treatment) step can be applied to the matrix material (120) provided onto a substrate for the purposes of drying and of reducing the solvent remaining therein. The prebaking step can be carried out at a temperature of generally 50 to 150° C., preferably 90 to 130° C. for 10 to 600 seconds, preferably 30 to 400 seconds on a hot-plate or for 1 to 30 minutes in a clean oven.

Exposing Step as Step (c) to Cure the Perhydropolysilazane

In a preferable embodiment of the present invention, after the coating of the perhydropolysilazane is formed, the surface thereof can be exposed to vacuum ultraviolet (hereafter “VUV”) light having peak wavelength at 172 nm or at 185 nm. As a light source for the exposure, it is possible to use any publically known VUV light source. Energy of the exposure light depends on the light source and the thickness of the coating, but is generally 10 to 2000 mJ/cm², preferably 20 to 1000 mJ/cm² to obtain the barrier layer obtained from PHPS.

According to the present invention, preferably, the barrier layer is SiN. Thus, preferably, all process can be carried out under an inert gas atmosphere. More preferably, all process can be carried out under purified nitrogen atmosphere to minimize oxygen density in the fabrication atmosphere.

In a preferred embodiment of the present invention, all fabrication process except for VUV light irradiation process as step (c) can be carried out under yellow light condition.

In another aspect, the present invention furthermore relates to method for preparing the optical device (200), wherein the method comprises following step (A);
(A) Providing the color conversion sheet (100) in an optical device

The invention is described in more detail in reference to the following examples, which are only illustrative and do not limit the scope of the invention.

### EXAMPLES

### Example 1

FIG. 1 discloses one example of a color conversion sheet (100) of the present invention including at least one nanosized fluorescent material (110) (for example, red and/or green), a matrix material (120), and a barrier layer (130). The color conversion sheet (100) can be peeled off from a substrate (140) shown in FIG. 1.

### Example 2

FIG. 2 shows one example of an optical device (200) of the present invention, including at least one nanosized fluorescent material (210) (for example, red and/or green), a matrix material (220), a barrier layer (230), and light emitting diode element (240). Other components such as a substrate (250) is an optional.

### Example 3

FIG. 3 shows one example of an optical device of the present invention.

Each feature disclosed in this specification, unless stated otherwise, may be replaced by alternative features serving the same, equivalent, or similar purpose. Thus, unless stated otherwise, each feature disclosed is but one example of a generic series of equivalent or similar features.

### DEFINITION OF TERMS

The term “transparent” means at least around 60% of incident light transmittal at the thickness used in an optical device and at a wavelength or a range of wavelength used during operation of an optical device. Preferably, it is over 70%, more preferably, over 75%, the most preferably, it is over 80%.

The term “fluorescent” is defined as the physical process of light emission by a substance that has absorbed light or other electromagnetic radiation. It is a form of luminescence. In most cases, the emitted light has a longer wavelength, and therefore lower energy, than the absorbed radiation.

The term “semiconductor” means a material which has electrical conductivity to a degree between that of a conductor (such as copper) and that of an insulator (such as glass) at room temperature.

The term “inorganic” means any material not containing carbon atoms or any compound that containing carbon atoms ionically bound to other atoms such as carbon monoxide, carbon dioxide, carbonates, cyanides, cyanates, carbides, and thiocyanates.

The term “emission” means the emission of electromagnetic waves by electron transitions in atoms and molecules.

The term “photosensitive” means that the respective composition chemically reacts in response to suitable light irradiation. The light is usually chosen from visible or UV light. The photosensitive response includes hardening or softening of the composition, preferably hardening. Preferably the photosensitive composition is a photo-polymerizable composition.

The working examples 1-11 below provide descriptions of the present invention, as well as an in detail description of their fabrication.

### WORKING EXAMPLES

### Working Example 1: PVA+Q-Rod/NN-PHPS

5 w % polyvinyl alcohol (hereafter “PVA”) water solution was added into a water based 3 wt. % q-rod solution (w=3% q-rods having polyethylenimine (hereafter “PEI”) ligand (polar)) at 80° C. under Nitrogen condition under stirring.

*(0.5 g PVA+9.5 g q-rod solution (polymer 0.5 g/q-rod 0.285 g)=around 64 wt. % polymer/36 wt. % q-rods)

The obtained solution was spincoated onto a cleaned three inch glass wafer, and then it was dried at 120° C. for 5 minutes, then it was put into a vacuum chamber at 50° C. overnight.

Then, perhydropolysilazane (hereafter “PHPS”) solution (“PHPS NN 120-20” containing Dibutylether solution; from Merck) was spincoated on top of the PVA layer and dried at 120° C. for 5 minutes.

After PHPS drying process, the PHPS layer was exposed to vacuum ultraviolet (hereafter “VUV”) light having peak wavelength 172 nm at 25 mW/cm² for 8 minutes with the VUV device (from IOT) under nitrogen atmosphere to accelerate Nitriding reaction of PHPS layer.

Then, the sample number PVA-1 having 0.3 um SiN layer coated on PVA/Q-rod layer was finally obtained.

All process were carried out under nitrogen atmosphere. And except for VUV light irradiation, all process were carried out under filtered yellow light condition.

### Working Example 2: PVA+Q-Rod/NN-PHPS

The sample PVA-2 having 0.3 um SiN layer coated on PVA/Q-rod layer was fabricated in the same manner as described in working example 1 except for VUV light irradiation having peak wavelength 172 nm at 25 mW/cm² was carried out for 4 minutes for NN-PHPS layer instead of 8 minutes irradiation.

### Working Example 3: PVA+Q-Rod/NL-PHPS

The sample PVA-3 having 0.3 um SiN layer coated on PVA/Q-rod layer was fabricated in the same manner as described in working example 1 except for NL-PHPS solution (product name “PHPS NL 120-20” containing Di-n-butyl-ether solution; from Merck) was used instead of NN-PHPS solution.

### Working Example 4: PVA+Q-Rod/NL-PHPS

The sample PVA-4 having 0.3 um SiN layer coated on PVA/Q-rod layer was fabricated in the same manner as described in working example 1 except for NL-PHPS solution was used instead of NN-PHPS solution, and VUV light irradiation having peak wavelength 172 nm at 25 mW/cm² was carried out for 4 minutes for NL-PHPS layer instead of 8 minutes irradiation.

### Comparative Example 1: PMMA+Q-Rod I/NN-PHPS

Q-rods having PEI ligands, Trioctylphosphine oxide (hereafter “TOPO”) ligands, or were not solved in polymethyl-methacrylate (hereafter “PMMA”) solution.

3% Q-rod having TOPO ligands in toluene solution was spincoated onto a cleaned three inch glass wafer and dried at 120° C. for 5 minutes. Then 20 wt % PMMA Anisole solution was spincoated on top of q-rods to fix q-rods on the surface of the glass and dried at 120° C. for 5 minutes. Sequentially, NN-PHPS solution was spincoated on top of the PMMA layer and dried at 120° C. for 5 minutes.

After PHPS drying process, the NN-PHPS layer was exposed to vacuum ultraviolet (hereafter “VUV”) light having peak wavelength 172 nm at 25 mW/cm² for 4 minutes with the VUV device (from IOT) under nitrogen atmosphere to accelerate Nitriding reaction of NN-PHPS layer.

Then, sample number “PMMA-5” having 0.3 um SiN layer was finally obtained.

All process were carried out under nitrogen atmosphere.

### Comparative Example 2: PMMA+Q-Rod/NL-PHPS

The sample PMMA-6 having 0.3 um SiN layer coated on PMMA/Q-rod layer was fabricated in the same manner as described in comparative example 1, except for NL-PHPS solution was used instead of NN-PHPS solution.

### Comparative Example 3: PS+Q-Rod/NN-PHPS

The sample PS-7 having 0.3 um SiN layer coated on PS/Q-rod layer was fabricated in the same manner as described in comparative example 1, except for polystyrene was used instead of PMMA.

### Comparative Example 4: PS+Q-Rod/NL-PHPS

The sample PS-8 having 0.3 um SiN layer coated on PS/Q-rod layer was fabricated in the same manner as described in comparative example 1, except for polystyrene was used instead of PMMA, and NL-PHPS solution was used instead of NN-PHPS solution.

### Working Example 5: QY Evaluation

The absolute PL quantum yield (hereafter “QY”) of each sample PVA-1, PVA-2, PVA-3, PVA-4, PMMA-5, PMMA-6, PS-7, and PS-8 was measured by Quantaurus-QY Absolute PL quantum yields measurement system C11347-11 (Hamamatsu).

FIG. 4 shows the results of the measurement.

### Comparative Example 5: PVA+Q-Rod without any PHPS Layer

The sample PVA 9 was fabricated in the same manner as described in working example 1, except for any PHPS layer was not fabricated onto PVA/q-rod layer.

### Working Example 6: QY Evaluation

The sample PVA-1 obtained in working example 1, and PVA 9 obtained in comparative example 5, were stored in ambient atmosphere at 85° C. The absolute PL quantum yield (hereafter “QY”) of PVA-1 obtained in working example 1, and PVA 9 obtained in comparative example 5, was each independently measured by Quantaurus-QY Absolute PL quantum yields measurement system C11347-11 (Hamamatsu).

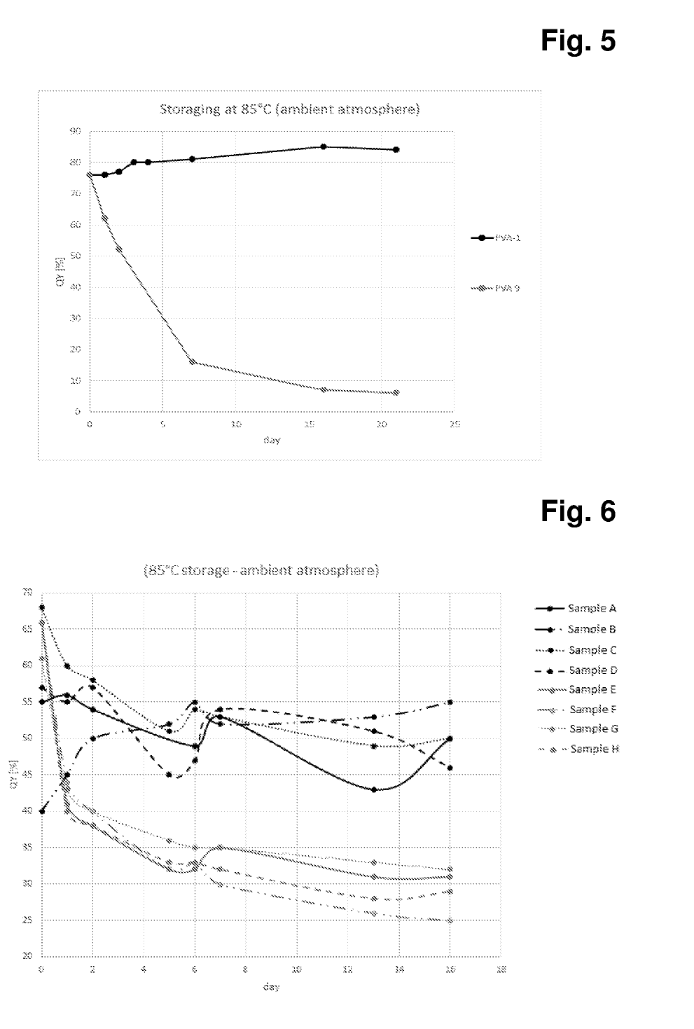

Table 2 and FIG. 5 shows the results of the measurement.

TABLE 2

| | | | Day | | | | | | | |
|---|---|---|---|---|---|---|---|---|---|---|
| | | | 0 | 1 | 2 | 3 | 4 | 7 | 16 | 21 |
| PVA-1 | 85° C. | QY | 76 | 76 | 77 | 80 | 80 | 81 | 85 | 84 |
| PVA 9 | 85° C. | QY | 76 | 62 | 52 | — | — | 16 | 7 | 6 |

### Working Example 7: Organopolysilazanes (25 wt. % in Heptane)+Q-Rod/NN-PHPS

3% Q-rod having TOPO ligands in toluene was added into organopolzsilayane (25 wt. % in Heptane) A represented by the general formula —[SiR₂—NH]— (R═H and CH₃) under Nitrogen condition under stirring. The weight ratio of 3% Q-rod having TOPO ligands in toluene and organopolzsilayane (25 wt. % in Heptane) was 1:4.

The obtained solution was spincoated onto a cleaned 3*3 cm glass substrate for 30 second at 1000 rpm. Then it was cured at 130° C. for 5 hours on a hotplate.

Afterwards, NN-PHPS (20% in Di-n-butylether) solution was spincoated on top of the MOP/Q-rod layer for 30 second at 2500 rpm, and dried at 120° C. for 2 minutes on a hotplate. After the drying process, then cured under VUV (172 nm) for 30 min at 5 W/cm². Then the sample A was fabricated.

### Working Example 8: Organopolysilazanes (25 wt. % in Heptane)+Q-Rod/NN-PHPS

Sample B was fabricated in the same manner as described in working example 7, except for organopolzsilayane (25 wt. % in Heptane) B represented by the general formula —[SiR₂—NH]— (R═H and CH₃) was used instead of organopolzsilayane (25 wt. % in Heptane) A.

### Working Example 9: Organopolysilazanes (25 wt. % in Heptane)+Q-Rod/NN-PHPS

Sample C was fabricated in the same manner as described in working example 7, except for organopolzsilayane (25 wt. % in Heptane) C represented by the formula —[Si(CH₃)₂—NH]a-[SiH(CH₃)—NH]b-[Si(CH₃)(CH═CH₂)—NH]c- containing 0.1 wt. % Luperox® (from Arkema group) was used instead of organopolzsilayane (25 wt. % in Heptane) A.

### Working Example 10: Organopolysilazanes (25 wt % in Heptane) with Luperox®+Q-Rod/NN-PHPS

Sample D was fabricated in the same manner as described in working example 7, except for organopolzsilayane (25 wt % in Heptane) A represented by the general formula —[SiR₂—NH]— (R═H and CH₃) was used instead of organopolzsilayane (25 wt. % in Heptane) A.

### Comparative Example 6: Organopolysilazanes (25 wt. % in Heptane)+Q-Rod without any PHPS Layer

The sample E was fabricated in the same manner as described in working example 7, except for any PHPS layer was not fabricated.

### Comparative Example 7: Organopolysilazanes (25 wt. % in Heptane)+Q-Rod without any PHPS Layer

The sample F was fabricated in the same manner as described in working example 8, except for any PHPS layer was not fabricated.

### Comparative Example 8: Organopolysilazanes (25 wt. % in Heptane)+Q-Rod without any PHPS Layer

The sample G was fabricated in the same manner as described in working example 9, except for any PHPS layer was not fabricated.

### Comparative Example 9: Organopolysilazanes (25 wt. % in Heptane)+Q-Rod without any PHPS Layer

The sample H was fabricated in the same manner as described in working example 10, except for any PHPS layer was not fabricated.

### Working Example 11: QY Evaluation

The samples A, B, C and D obtained in working examples 7 to 10, and the samples E to H obtained in comparative examples 6 to 9, were stored in ambient atmosphere at 85° C.

The absolute PL quantum yield (hereafter “QY”) of PVA-1 obtained in working example 1, and PVA 9 obtained in comparative example 5, was each independently measured by Quantaurus-QY Absolute PL quantum yields measurement system C11347-11 (Hamamatsu).

Table 3 and FIG. 6 shows the results of the measurement.

TABLE 3

| | | | | | day | | | | | | | |
|---|---|---|---|---|---|---|---|---|---|---|---|---|
| Sample No. | Curing | PHPS layer | Storage | | 0 | 1 | 2 | 5 | 6 | 7 | 13 | 16 |
| Sample A | 130° C. 5 h | Yes | at 85° C. | QE | 55 | 56 | 54 | — | 49 | 53 | 43 | 50 |
| Sample B | 130° C. 5 h | Yes | at 85° C. | QE | 40 | 45 | 50 | 52 | 55 | 52 | 53 | 55 |
| Sample C | 130° C. 5 h | Yes | at 85° C. | QE | 68 | 60 | 58 | 51 | 54 | 53 | 49 | 50 |
| Sample D | 130° C. 5 h | Yes | at 85° C. | QE | 57 | 55 | 57 | 45 | 47 | 54 | 51 | 46 |
| Sample E | 130° C. 5 h | No | at 85° C. | QE | 66 | 41 | 38 | 32 | 32 | 35 | 31 | 31 |
| Sample F | 130° C. 5 h | No | at 85° C. | QE | 66 | 44 | 40 | 32 | 33 | 30 | 26 | 25 |
| Sample G | 130° C. 5 h | No | at 85° C. | QE | 61 | 43 | 40 | 36 | 35 | 35 | 33 | 32 |
| Sample H | 130° C. 5 h | No | at 85° C. | QE | 66 | 40 | 38 | 33 | 33 | 32 | 28 | 29 |

1. A color conversion sheet (100) comprising at least one nanosized fluorescent material (110), a matrix material (120) and a barrier layer (130), wherein the barrier layer (130) is placed onto the outermost surface of the matrix material (120).

2. The color conversion sheet (100) according to claim 1, wherein the barrier layer (130) is a layer obtained from perhydropolysilazane.

3. The color conversion sheet (100) according to claim 1, wherein the barrier layer (130) comprises a gradient structure comprised of an outermost part and subsequent part in the layer, wherein the outermost part consists of silicon nitride.

4. The color conversion sheet (100) according to claim 1, wherein the gradient is a hydrogen content.

5. The color conversion sheet (100) according to claim 1, wherein the outermost part of the gradient structure to the matrix material (120) comprises higher amount of hydrogen than the opposite side of the gradient structure to the barrier layer (130).

6. The color conversion sheet (100) according to claim 1, wherein the barrier layer (130) has the refractive index in the range from 1.38 to 1.85.

7. The color conversion sheet according to claim 1, wherein the barrier layer (130) has the refractive index in the range from 1.45 to 1.60.

8. The color conversion sheet (100) according to claim 1, wherein the matrix material (120) is selected from the group consisting of polysilazanes, water soluble polymers and a combination of any of these.

9. The color conversion sheet (100) according to claim 1, wherein the matrix material (120) is selected from the group consisting of organopolysilazanes, substituted or unsubstituted polyvinylalcohols and a combination of any of these.

10. The color conversion sheet (100) according to claim 1, wherein the color conversion sheet (100) further comprises an UV cut layer in between the matrix material (120) and the barrier layer (130).

11. (canceled)

12. An optical device (200) comprising the color conversion sheet (100) according to claim 1.

13. The optical device (200) according to claim 12, wherein the optical device further comprises a light emitting diode element (240).

14. An optical device (200), wherein the optical device (200) comprises at least one nanosized fluorescent material (210), a matrix material (220), a barrier layer (230), and a light emitting diode element (240), wherein the barrier layer (230) is placed onto the outermost surface of the matrix material (220).

15. Method for preparing the color conversion sheet (100), wherein the method comprises following steps (a) and (c) in this sequence;
(a) providing at least one nanosized fluorescent material (110), and a matrix material (120) onto a substrate,
(b) providing perhydropolysilazane solution onto the surface of the matrix material, and
(c) exposing the perhydropolysilazane to vacuum ultraviolet light.

16. Method for preparing the color conversion sheet (100) according to claim 15, wherein the method further comprises step (d) after step (b) and before step (c);
(d) drying the perhydropolysilazane solution.

17. Method for preparing the optical device (200), wherein the method comprises following step (A);
(A) providing the color conversion sheet (100) according to claim 1, in an optical device.
